(19) United States
(12) Patent Application Publication
(10) Pub. No.: US 2009/0314328 A1
(43) Pub. Date: Dec. 24, 2009

(54) PHOTOVOLTAIC MODULE

(75) Inventor: Ivan Saha, Chennai (IN)

Correspondence Address: DARBY & DARBY P.C., P.O. BOX 770, Church Street Station, New York, NY, 10008-0770, US

(73) Assignee: MOSER BAER PHOTOVOLTAIC LIMITED, Chennai (IN)

(21) Appl. No.: 12/178,022

(22) Filed: Jul. 23, 2008

(30) Foreign Application Priority Data
Jun. 24, 2008 (IN) 2008/CHE/007136

(51) Int. Cl. H01L 31/042; H01L 21/67

(52) U.S. Cl. 136/246; 29/25.01; 257/E31.001

(57) ABSTRACT

Embodiments include a photovoltaic module for generating electricity from solar energy, said photovoltaic module having a base substrate; one or more photovoltaic strips arranged over said base substrate, wherein spaces are formed in between adjacent photovoltaic strips; a plurality of optical vees located in the spaces between said photovoltaic strips, such that one or more cavities are formed between said optical vees; and a polymeric material in a fluid state is introduced over the photovoltaic strips and the optical vees, such that the polymeric material fills the cavities between the optical vees and forms a plurality of molded concentrating elements for concentrating solar energy over the photovoltaic strips. Other embodiments include systems for generating electricity using the photovoltaic module. Yet other embodiments relate to methods of manufacturing the photovoltaic module and systems for generating electricity using the photovoltaic module.

### CROSS REFERENCE TO RELATED APPLICATIONS

This application claims the benefit of Indian Patent Application Number 2008/CHE/007136, filed on Jun. 24, 2008, which is hereby incorporated by reference in its entirety.

### BACKGROUND

The present invention relates, in general, to photovoltaic modules. More specifically, the present invention relates to a method for fabricating a photovoltaic module.

Photovoltaic cells are large area semiconductor diodes that convert incident solar energy into electrical energy. Photovoltaic cells are often made of silicon wafers. The photovoltaic cells are combined in series and/or parallel to form photovoltaic modules.

In order to increase the power output and reduce the cost of the photovoltaic modules, silicon is partly replaced by cheap plastic reflective/refractive optics to concentrate Sun's radiation in smaller area. In one such approach, high concentrators are employed to concentrate the incident radiation over the photovoltaic cells. High concentrators require direct solar rays in order to work appropriately hence call for solar tracking. Moreover, high concentration leads to generation of excessive heat in the cells and, therefore requires a suitable cooling mechanism to minimize damage and efficiency reduction.

In another method, low concentrators have been employed for reduction of total cell area required for efficient energy conversion. These concentrators do not require solar trackers and complex cooling mechanism, thus are more economical. However, optical defects typically occur during the fabrication of low concentrator photovoltaic modules. For example, empty spaces or air bubbles may be left between various components of the photovoltaic module and the low concentrators. This, in turn, reduces the efficiency of the photovoltaic cells. In addition, such photovoltaic modules are not economical, due to higher rejections during manufacturing/quality control processes, low efficiencies owing to defects and requirement of precise assembly process.

In light of the foregoing discussion, there is a need for a photovoltaic module (and a fabrication method and system thereof) that is suitable for mass manufacturing, has lower cost, has substantially reduced defects, has higher efficiency, and has ease of manufacturing compared to conventional low concentrator photovoltaic modules.

### SUMMARY

An object of the present invention is to provide a photovoltaic module (and a fabrication method and system thereof) that is suitable for mass manufacturing.

Another object of the present invention is to provide the photovoltaic module that has lower cost compared to conventional low concentrator photovoltaic modules. The photovoltaic module should be fabricated with lesser amount of semiconductor material.

Yet another object of the present invention is to provide the photovoltaic module that has substantially reduced defects compared to conventional low concentrator photovoltaic modules. This is to eliminate optical defects in assembly and production of the photovoltaic module.

Still another object of the present invention is to provide the photovoltaic module that has higher efficiency compared to conventional low concentrator photovoltaic modules. This is to maximize the power output of the photovoltaic module.

Still another object of the present invention is to provide the photovoltaic module that has ease of manufacturing compared to conventional low concentrator photovoltaic modules.

Embodiments of the present invention provide a photovoltaic module for generating electricity from solar energy. The photovoltaic module includes a base substrate for providing a support to the photovoltaic module. One or more photovoltaic strips are arranged over the base substrate in a predefined manner. The predefined manner may, for example, be a series and/or parallel arrangement, such that electrical output is maximized. The photovoltaic strips may be formed by dicing a semiconductor wafer. The photovoltaic strips are arranged with spaces in between adjacent photovoltaic strips. The photovoltaic strips are connected through one or more conductors in series and/or parallel.

A plurality of optical vees is placed in the spaces between the photovoltaic strips, such that one or more cavities is formed between adjacent optical vees. In an embodiment of the present invention, the cavities formed between adjacent optical vees forms a trapezoidal shape in cross-section. The optical vees may, for example, be made of glass, plastics, and acrylics.

A polymeric material in a fluid state is introduced over the photovoltaic strips and the optical vees, such that the polymeric material fills the cavities between the optical vees and forms a plurality of molded concentrating elements for concentrating solar energy over the photovoltaic strips. The molded concentrating elements take the shape of the cavities in cross-section. The polymeric material can be any material that is tolerant to moisture, Ultra Violet (UV) radiation, abrasion, and natural temperature variations. The refractive index of the polymeric material may, for example, be 1.5 or above. Examples of the polymeric material include, but are not limited to, Ethyl Vinyl Acetate (EVA), silicone, Thermoplastic Poly-Urethane (TPU), Poly Vinyl Butyral (PVB), acrylic, polycarbonates, and synthetic resins. In an embodiment of the present invention, the molded concentrating elements form a trapezoidal shape in cross-section. The molded concentrating elements are optically coupled to the photovoltaic strips. No space or air bubble is left between the molded concentrating elements and the optical vees, and between the molded concentrating elements and the photovoltaic strips which minimize optical defects.

In accordance with an embodiment of the present invention, each optical vee includes a first medium and a second medium underlying the first medium, where the ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. A medium boundary is formed at the interface of the first medium and the second medium, at a predefined angle, such that rays incident within an angular limit of normal to the base substrate are total internally reflected at the medium boundary and fall on the photovoltaic strips. In accordance with another embodiment of the present invention, the optical vees are solid, and the refractive index of the optical vees is lesser than the refractive index of the molded concentrating elements. In such a case, a medium boundary is formed at the interface of the optical vees and the molded concentrating elements, at a predefined angle, such that rays incident within an angular limit of normal to the base substrate are total internally reflected at the medium boundary and fall on the photovoltaic strips.

Electromagnetic radiation falling on the molded concentrating elements is concentrated over the photovoltaic strips, as explained above. In order to increase the efficiency of concentration, various parameters, such as the refractive indexes of the optical vees and the molded concentrating elements, may be manipulated. In an embodiment of the present invention, during molding of the molded concentrating elements, the extra volume of the polymeric material forms a layer of the polymeric material over the molded concentrating elements and the optical vees. In this embodiment, the layer protects the photovoltaic module from environmental damages. Further, the layer of the polymeric material may be coated with an anti-reflective coating to reduce loss of solar energy incident on the photovoltaic module. In such a case, no reflection occurs at the surface of the molded concentrating elements, thereby increasing the efficiency of concentration. In accordance with an embodiment of the present invention, no refraction occurs at a medium boundary between the first medium of the optical vees and the molded concentrating elements, when the refractive index of the first medium of the optical vees is substantially similar to the refractive index of the molded concentrating elements. In such a case, the medium boundary between the first medium and the molded concentrating elements is optically transparent. The refractive indexes of the molded concentrating elements and the first medium are more than the refractive index of air or vacuum.

In an embodiment of the present invention, the photovoltaic module also includes a transparent member positioned over the molded concentrating elements. The transparent member is optically coupled to the molded concentrating elements. The refractive index of the transparent member is substantially similar to the refractive index of at least a portion of the molded concentrating elements. The transparent member is coated with an anti-reflective coating to reduce loss of solar energy incident on the photovoltaic module.

The fabrication of the photovoltaic module involves similar processes and machines that are required to fabricate conventional photovoltaic modules. Therefore, the method of fabrication of the photovoltaic module is easy, quick and cost effective.

In addition, the molded concentrating elements are not formed separately, and are rather formed by molding a suitable polymeric material over the photovoltaic strips and the optical vees. Therefore, optical defects, such as void spaces and air bubbles within the photovoltaic module, are minimized, while quickening the process of fabrication, and reducing cost of assembly and fabrication.

Moreover, the photovoltaic module provides maximized outputs, at appropriate configurations of the photovoltaic strips and appropriate levels of concentration. The concentrating elements provide concentration ratios between 5:1 and 1.5:1, and concentrate solar energy onto the photovoltaic strips. Therefore, the photovoltaic module requires lesser amount of semiconductor material to generate same electrical output compared to conventional flat photovoltaic modules.

### BRIEF DESCRIPTION OF DRAWINGS

Embodiments of the present invention will hereinafter be described in conjunction with the appended drawings provided to illustrate and not to limit the present invention, wherein like designations denote like elements, and in which:

FIG. 1 illustrates a blown-up view of a photovoltaic module, in accordance with an embodiment of the present invention;

FIG. 2 illustrates a cross-sectional view of the photovoltaic module, in accordance with an embodiment of the present invention;

FIG. 3 illustrates how a plurality of photovoltaic strips is connected through a plurality of conductors, in accordance with an embodiment of the present invention;

FIG. 4 illustrates the process of lamination, in accordance with an embodiment of the present invention;

FIG. 5 is a perspective view of a base substrate, in accordance with an embodiment of the present invention;

FIG. 6 is a perspective view of a string configuration of photovoltaic strips, in accordance with an embodiment of the present invention;

FIG. 7 is a perspective view illustrating a plurality of optical vees placed with the string configuration, in accordance with an embodiment of the present invention;

FIG. 8 is a perspective view illustrating a lay-up of a transparent member over molded EVA elements, in accordance with an embodiment of the present invention;

FIG. 9 is a perspective view of the photovoltaic module so formed, in accordance with an embodiment of the present invention;

FIG. 10 is a flow diagram illustrating a method for fabricating a photovoltaic module, in accordance with an embodiment of the present invention;

FIG. 11 is a flow diagram illustrating a method for fabricating a photovoltaic module, in accordance with another embodiment of the present invention;

FIG. 12 is a schematic diagram illustrating a configuration of a plurality of photovoltaic strips, in accordance with another embodiment of the present invention;

FIG. 13 is a cross-sectional view illustrating how electromagnetic radiation is concentrated over a photovoltaic strip, in accordance with an embodiment of the present invention;

FIG. 14 is a cross-sectional view illustrating how electromagnetic radiation is concentrated over a photovoltaic strip, in accordance with another embodiment of the present invention;

FIG. 15 illustrates how the level of concentration can be varied, in accordance with an embodiment of the present invention;

FIG. 16 illustrates how the level of concentration can be varied, in accordance with an embodiment of the present invention;

FIG. 17 illustrates a simulation of the output of a photovoltaic strip of size 125 mm×12 mm, in accordance with an embodiment of the present invention;

FIG. 18 illustrates a method for manufacturing a system for generating electricity from solar energy, in accordance with an embodiment of the present invention;

FIG. 19 illustrates a method for manufacturing a system for generating electricity from solar energy, in accordance with another embodiment of the present invention;

FIG. 20 illustrates a system for manufacturing photovoltaic module, in accordance with an embodiment of the present invention;

FIG. 21 illustrates a system for generating electricity from solar energy, in accordance with an embodiment of the present invention; and

FIG. 22 illustrates a system for generating electricity from solar energy, in accordance with another embodiment of the present invention.

FIG. 23 illustrates a blown up view of the photovoltaic module, in accordance with another embodiment of the present invention.

### DETAILED DESCRIPTION

As used in the specification and claims, the singular forms “a”, “an” and “the” include plural references unless the context clearly dictates otherwise. For example, the term “a photovoltaic module” may include a plurality of photovoltaic modules unless the context clearly dictates otherwise. A term having “-containing” such as “metal-containing” contains a metal but is open to other substances, but need not contain any other substance other than a metal.

Embodiments of the present invention provide a method, system and apparatus for generating electricity from solar energy, and a method and system for fabricating the photovoltaic module. In the description herein for embodiments of the present invention, numerous specific details are provided, such as examples of components and/or mechanisms, to provide a thorough understanding of embodiments of the present invention. One skilled in the relevant art will recognize, however, that an embodiment of the present invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

### GLOSSARY

Photovoltaic module: A photovoltaic module is a packaged interconnected assembly of photovoltaic strips, which converts solar energy into electricity by the photovoltaic effect.
Integrated manner: In terms of the apparatus (photovoltaic module), it means that the electrically connected photovoltaic strips and the concentrator elements form an integrated and functional unit only at the module level. Any sub-part of the apparatus is not a functionally independent unit. In terms of the method of manufacturing in an integrated manner, it means that the assembly of the apparatus (photovoltaic module) consisting of photovoltaic strips, optical vees, and transparent member on the base substrate is carried out in one integrated sequence of operations without making functionally separate sub-units or sub-assemblies.
Base substrate: A base substrate is a term used to describe the base member of photovoltaic module on which photovoltaic strips are placed. The base substrate has an electrically insulated top surface.
Photovoltaic strip: A photovoltaic strip is a part of semiconductor wafer used in the fabrication of photovoltaic module.
Optical vee: An optical vee is a member with at least two surfaces arranged in the shape of an ‘inverted-V’.
Polymeric material: A polymeric material is a substance composed of molecules with large molecular mass composed of repeating structural units, or monomers, connected by covalent chemical bonds.
Concentrating element: A concentrating element is an optical member that acts as a medium for concentrating sunlight.
Conductor: An element for electrically connecting photovoltaic strips to form a circuit.
Space: Space is the area between the adjacent photovoltaic strips.
Cavity: Cavity is three-dimensional region formed between adjacent optical vees and the photovoltaic strip that is placed between the adjacent optical vees.
Medium boundary: Medium boundary is a boundary between two mediums. For example, a medium boundary is formed at a boundary between glass and air.
Optically coupled: Optically coupled means a connection of two media of different/same refractive index so that there is no loss of light at the medium boundary.
Laminate: Laminate is an entire assembly of the photovoltaic strip, base substrate, optical vee and transparent member joined by the polymeric material.
Transparent member: Transparent member is an optically clear member placed over the photovoltaic module to seal and protect the photovoltaic module from environmental damage.
Anti-reflective coating: Anti-reflective coating is a coating over the transparent member to reduce loss of solar energy incident on the photovoltaic module.
Dicer: A dicer is for dicing a semiconductor wafer to form the photovoltaic strips.
Stringer: A stringer is for connecting the photovoltaic strips through one or more conductors.
Strip-arranger: A strip arranger is for arranging the photovoltaic strips over a base substrate.
Optical-vee placer: An optical-vee placer is for placing the optical vees in the spaces between the photovoltaic strips.
Dispenser: A dispenser is for dispensing the polymeric material in a fluid state over the cavities to form the molded concentrating elements.
Positioning unit: A positioning unit is for positioning the transparent member over the optical vees.
Power-consuming unit: A power-consuming unit is for consuming and/or storing the power generated by the photovoltaic module.
AC Load: AC Load is a device that operates on Alternating Current (AC).

DC Load: DC Load is a device that operates on Direct Current (DC).

Charge controller: A charge controller controls the amount of charge consumed by the power-consuming unit.
Inverter: An inverter converts the electricity from a first form to a second form. For example, it converts electricity from AC to DC and vice-versa.

Embodiments of the photovoltaic module include a base substrate (also referred as backpanel), for example, made of anodized aluminum for providing a support to the photovoltaic module. Photovoltaic strips are arranged over the base substrate in strings with series and/or parallel arrangement, such that electrical output is maximized. The photovoltaic strips are arranged with spaces in between adjacent photovoltaic strips. A plurality of transparent and hollow optical vees are placed in the spaces between the photovoltaic strips and bonded to the aluminum backpanel. A plurality of trapezoidal shaped cavities is formed between adjacent optical vees. The trapezoidal shaped cavities have air/vacuum enclosed within them.

An optically clear liquid polymeric material (EVA) of refractive index 1.5 could be made to flow over the optical vees and inside the trapezoidal cavities between the optical vees to form a molten molded EVA coating. An optically clear, low iron content glass cover sheet could be placed on the optical vees while the molded EVA coating is still in a molten form. The molten EVA coating is cured and solidified, thereby bonding the glass sheet to the optical vees, thereby forming an embodiment of the photovoltaic module.

When light falls on the photovoltaic module, it is total internally reflected at the polymeric material (EVA)-air interface and gets concentrated according to the geometric concentration ratio defined by the entry and exit aperture of the molded polymeric material (EVA). In the photovoltaic module, the cover glass and the aluminum backpanel are generally not sealed at the edges. Instead, the molded EVA coating over the optical vees seals the optical vees and the photovoltaic strips from moisture.

The photovoltaic module includes a base substrate for providing a support to the photovoltaic module. One or more photovoltaic strips are arranged over the base substrate in a predefined manner. The predefined manner may, for example, be a series and/or parallel arrangement, such that electrical output is maximized. For example, the photovoltaic strips may be rectangular in shape, and may be arranged parallel to each other with spaces in between two adjacent photovoltaic strips. The photovoltaic strips may be formed by dicing a semiconductor wafer. In another example, the photovoltaic strips may be circular or arc-like in shape, and may be arranged in the form of concentric circles. The photovoltaic strips may also be square, triangular, or any other shape, in accordance with a desired configuration. The photovoltaic strips are arranged substantially parallel to each other with spaces in between adjacent photovoltaic strips. The photovoltaic strips are connected through one or more conductors in series and/or parallel.

A plurality of optical vees is placed in the spaces between the photovoltaic strips, such that one or more cavities is formed between adjacent optical vees. For example, the optical vees may be placed in a manner that each photovoltaic strip has two adjacent optical vees. In an embodiment of the present invention, the cavities formed between adjacent optical vees forms a trapezoidal shape in cross-section.

A polymeric material in a fluid state is introduced over the photovoltaic strips and the optical vees, such that the polymeric material fills the cavities between the optical vees and forms a plurality of molded concentrating elements for concentrating solar energy over the photovoltaic strips. The molded concentrating elements take the shape of the cavities in cross-section. The polymeric material can be any material that is tolerant to moisture, Ultra Violet (UV) radiation, abrasion, and natural temperature variations. The refractive index of the polymeric material may, for example, be 1.5 or above. Examples of the polymeric material include, but are not limited to, Ethyl Vinyl Acetate (EVA), silicone, Thermoplastic Poly-Urethane (TPU), Poly Vinyl Butyral (PVB), acrylics, polycarbonates, and synthetic resins. In an embodiment of the present invention, the molded concentrating elements form a trapezoidal shape in cross-section. The molded concentrating elements are optically coupled to the photovoltaic strips. No space or air bubble is left between the molded concentrating elements and the optical vees, and between the molded concentrating elements and the photovoltaic strips which minimizes the optical defects.

In accordance with an embodiment of the present invention, each optical vee includes a first medium and a second medium underlying the first medium, where the ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. A medium boundary is formed at the interface of the first medium and the second medium, at a predefined angle, such that rays incident within an angular limit of normal to the base substrate are total internally reflected at the medium boundary and fall on the photovoltaic strips. In accordance with another embodiment of the present invention, the optical vees are solid, and the refractive index of the optical vees is lesser than the refractive index of the molded concentrating elements. In such a case, a medium boundary is formed at the interface of the optical vees and the molded concentrating elements, at a predefined angle, such that rays incident within an angular limit of normal to the base substrate are total internally reflected at the medium boundary and fall on the photovoltaic strips. The optical vees may, for example, be made of any material that provides desired optical properties. Examples of such material include, but are not limited to, glass, plastics, and acrylics.

Electromagnetic radiation falling on the molded concentrating elements is concentrated over the photovoltaic strips, as explained above. In order to increase the efficiency of concentration, various parameters, such as the reflectivity of the molded concentrating elements, and the refractive indexes of the optical vees and the molded concentrating elements, may be manipulated. For example, the molded concentrating elements may be coated with an anti-reflective coating to reduce loss of solar energy incident on the photovoltaic module. In such a case, no reflection occurs at the surface of the molded concentrating elements, thereby increasing the efficiency of concentration. In accordance with an embodiment of the present invention, no refraction occurs at a medium boundary between the first medium of the optical vees and the molded concentrating elements, when the refractive index of the first medium of the optical vees is substantially similar to the refractive index of the molded concentrating elements. In such a case, the medium boundary between the first medium and the molded concentrating elements is optically transparent. The refractive indexes of the molded concentrating elements and the first medium are more than the refractive index of air or vacuum.

In an embodiment of the present invention, the photovoltaic module also includes a transparent member positioned over the molded concentrating elements. The transparent member is optically coupled to the molded concentrating elements. The refractive index of the transparent member is substantially similar to the refractive index of at least a portion of the molded concentrating elements. The transparent member is coated with an anti-reflective coating to reduce loss of solar energy incident on the photovoltaic module, in accordance with an embodiment of the present invention.

In an embodiment of the present invention, the photovoltaic module further includes a laminate encapsulating the base substrate, the photovoltaic strips, the optical vees and the molded concentrating elements. The laminate holds the photovoltaic module together.

The acceptance angle of the photovoltaic module is chosen, such that rays within the angular limit of normal to the photovoltaic module are total internally reflected towards the photovoltaic strips with minimal optical losses. Tracking mechanisms may be used to change the position of the photovoltaic module, in order to keep the rays normally incident upon the photovoltaic module while the sun moves across the sky. This further enhances the power output of the photovoltaic module.

The photovoltaic module can be used in various applications. For example, an array of photovoltaic modules may be used to generate electricity on a large scale for grid power supply. In another example, photovoltaic modules may be used to generate electricity on a small scale for home/office use. Alternatively, photovoltaic modules may be used to generate electricity for stand-alone electrical devices, such as automobiles and spacecraft. Details of these applications have been provided in conjunction with drawings below.

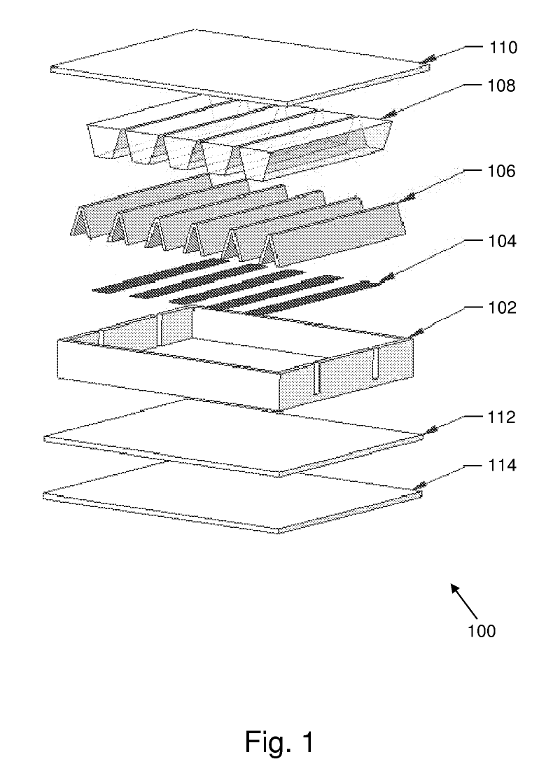

FIG. 1 illustrates a blown-up view of a photovoltaic module 300, in accordance with an embodiment of the present invention. Photovoltaic module 300 includes a base substrate 302, a plurality of photovoltaic strips 304, a plurality of optical vees 306, a plurality of molded concentrating elements 308, a transparent member 310, a laminate 312, and a supporting substrate 314.

Base substrate 302 provides support to photovoltaic module 300. With reference to FIG. 1, base substrate 302 is rectangular in shape. Base substrate 302 can be made of any material that is tolerant to moisture, Ultra Violet (UV) radiation, abrasion, and natural temperature variations. Examples of such materials include, but not limited to, aluminium, steel, plastics and suitable polycarbonates. In addition, base substrate 302 may, for example, be made of plastics with metal coating or plastics with high thermal conductivity fillers. Examples of such fillers include, but are not limited to, boron nitride (BN), aluminium oxide, (Al₂O₃), and metals. Base substrate 302 has an electrically insulated top surface. For example, base substrate 302 is coated with a layer of electrically insulating material, such as anodized aluminium.

Photovoltaic strips 304 are arranged over base substrate 302. With reference to FIG. 1, photovoltaic strips 304 are rectangular in shape and are arranged parallel to each other with spaces in between two adjacent photovoltaic strips. Photovoltaic strips 304 are made of a semiconductor material. Examples of semiconductors include, but are not limited to, monocrystalline silicon (c-Si), polycrystalline or multicrystalline silicon (poly-Si or mc-Si), ribbon silicon, cadmium telluride (CdTe), copper-indium diselenide (CuInSe₂), combinations of III-V, II-VI elements in the periodic table that have photovoltaic effect, copper indium/gallium diselenide (CIGS), gallium arsenide (GaAs), germanium (Ge), gallium indium phosphide (GalnP₂), organic semiconductors such as polymers and small-molecule compounds like polyphenylene vinylene, copper phthalocyanine and carbon fullerenes, amorphous silicon (a-Si or a-Si:H), protocrystalline silicon, and nanocrystalline silicon (nc-Si or nc-Si:H). When electromagnetic radiation falls over photovoltaic strips 304, electron-hole pairs are separated by some means before they recombine giving rise to a voltage. When a load is connected across the two electrodes the generated voltage drives a current producing electrical energy.

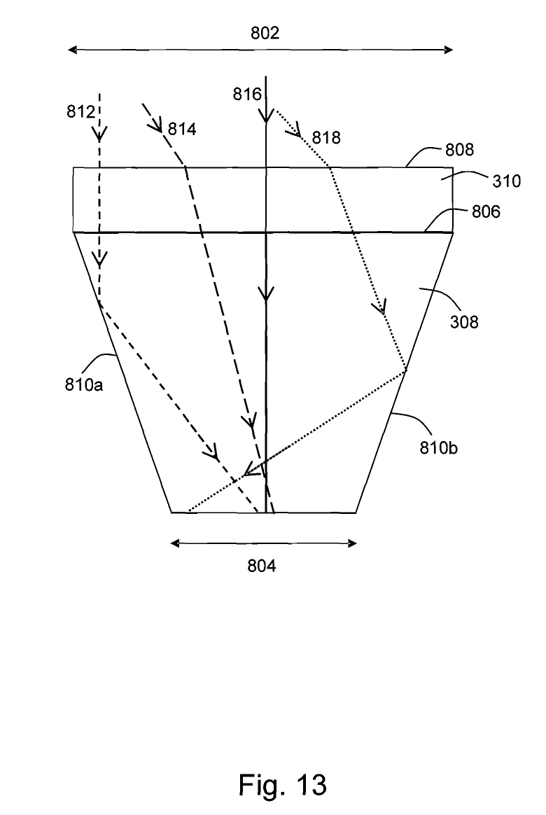

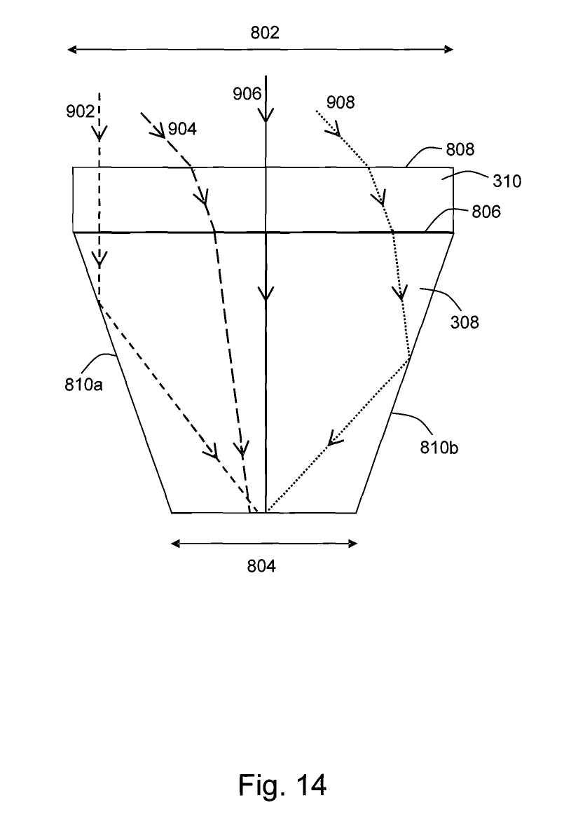

With reference to FIG. 1, optical vees 306 are placed in the spaces between photovoltaic strips 304 and at the outermost sides, such that a plurality of trapezoidal cavities is formed between optical vees 306. Molded concentrating elements 308 are formed over the trapezoidal cavities by pouring a polymeric material in a fluid state. Molded concentrating elements 308 are molded in the shape of the trapezoidal cavities. As mentioned above, no space or air bubble is left between molded concentrating elements 308 and photovoltaic strips 304, and between molded concentrating elements 308 and optical vees 306. Molded concentrating elements 308 are optically coupled to photovoltaic strips 304. Molded concentrating elements 308 concentrate the electromagnetic radiation over photovoltaic strips 304. In an embodiment of the present invention, molded concentrating elements 308 act as a laminate for encapsulating photovoltaic module 300. The level of concentration may be varied depending on the shape, size and refractive index of molded concentrating elements 308. Details of various levels of concentration have been provided in conjunction with FIGS. 13 and 14.

Transparent member 310 is optically coupled to molded concentrating elements 308, in accordance with an embodiment of the present invention. Transparent member 310 protects molded concentrating elements 308 and photovoltaic strips 304 from environmental damage, while allowing electromagnetic radiation falling on its surface to pass to molded concentrating elements 308. The refractive index of transparent member 310 can be varied, and the reflectivity of transparent member 310 can be minimized, to increase the efficiency of concentration. For example, transparent member 310 may be coated with an anti-reflective coating, so that reflection occurs at a medium boundary between air and transparent member 310 is minimized. In addition, no refraction occurs at a medium boundary between transparent member 310 and molded concentrating elements 308 when the refractive index of transparent member 310 is substantially similar to the refractive index of molded concentrating elements 308. Rays, incident on the medium boundary between transparent member 310 and molded concentrating elements 308, refract with an angle of refraction smaller than an angle of incidence when the refractive index of transparent member 310 is less than the refractive index of molded concentrating elements 308. The shape of transparent member may, for example, be flat or curved.

Laminate 312 is formed by a second polymeric material, and encapsulates photovoltaic strips 304, in accordance with an embodiment of the present invention. Laminate 312 holds photovoltaic module 300 and its components together, and protects photovoltaic module 300 against moisture, abrasion, and natural temperature variations. Supporting substrate 314 is used during the process of lamination, and is removed later.

It is to be understood that the specific designation for photovoltaic module 300 and its components is for the convenience of the reader and is not to be construed as limiting photovoltaic module 300 and its components to a specific number, size, shape, type, material, or arrangement.

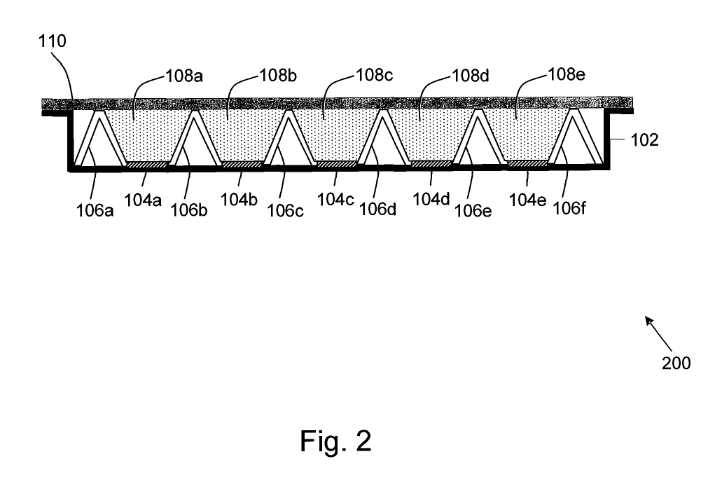

FIG. 2 illustrates a cross-sectional view of photovoltaic module 300, in accordance with an embodiment of the present invention. In FIG. 2, photovoltaic strips 304 are shown as a photovoltaic strip 304a, a photovoltaic strip 304b, a photovoltaic strip 304c, a photovoltaic strip 304d, and a photovoltaic strip 304e. Optical vees 306 are shown as an optical vee 306a, an optical vee 306b, an optical vee 306c, an optical vee 306d, an optical vee 306e, and an optical vee 306f. Molded concentrating elements 308 are shown as a molded concentrating element 308a, a molded concentrating element 308b, a molded concentrating element 308c, a molded concentrating element 308d, and a molded concentrating element 308e. With reference to FIG. 2, molded concentrating element 308a is molded in a cavity between optical vee 306a and optical vee 306b, molded concentrating element 308b is molded in a cavity between optical vee 306b and optical vee 306c, and so on. As mentioned above, no space or air bubble is left between molded concentrating elements 308 and photovoltaic strips 304, and between molded concentrating elements 308 and optical vees 306.

A single photovoltaic strip, a single optical vee and a single molded concentrating element are collectively termed as a ‘low concentrator unit’. A plurality of such low concentrator units may be combined together to form a photovoltaic module, in accordance with an embodiment of the present invention.

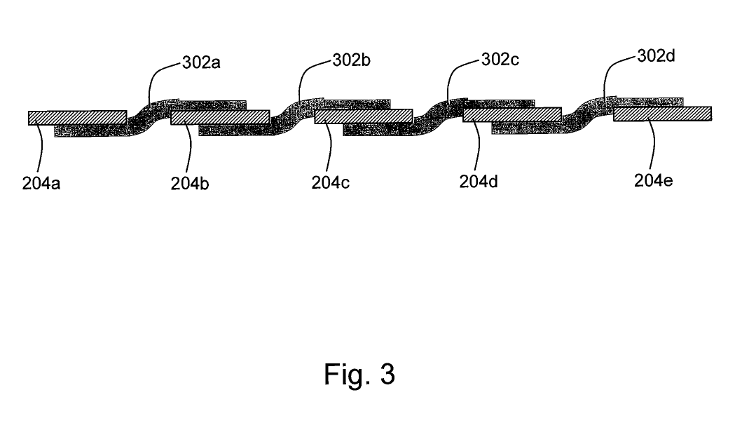

FIG. 3 illustrates how photovoltaic strips 304 are connected through a plurality of conductors, in accordance with an embodiment of the present invention. With reference to FIG. 3, photovoltaic strips 304 are connected in series. In such a configuration, the p-side of photovoltaic strip 304a is connected to the n-side of photovoltaic strip 304b using a conductor 502a, the p-side of photovoltaic strip 304b is connected to the n-side of photovoltaic strip 304c using a conductor 502b, the p-side of photovoltaic strip 304c is connected to the n-side of photovoltaic strip 304d using a conductor 502c, and the p-side of photovoltaic strip 304d is connected to the n-side of photovoltaic strip 304e using a conductor 502d.

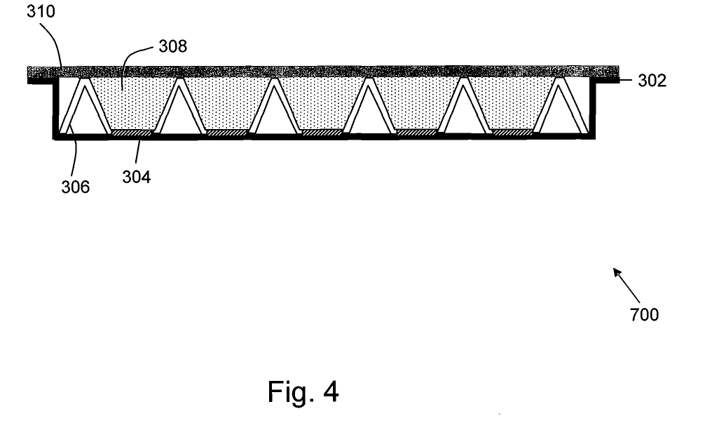

FIG. 4 illustrates the process of lamination 700, in accordance with an embodiment of the present invention. Photovoltaic strips 304, optical vees 306 and molded concentrating elements 308 are encapsulated with the second polymeric material. As mentioned above, the process of lamination is performed at a prescribed temperature and/or pressure in a vacuum environment using a laminator. The vacuum environment ensures that no air bubbles are formed within the laminate. The second polymeric material may, for example, be EVA, silicone, TPU, PVB, acrylics, polycarbonates, or synthetic resins. The second polymeric material can be any material that is tolerant to moisture, abrasion, and natural temperature variations.

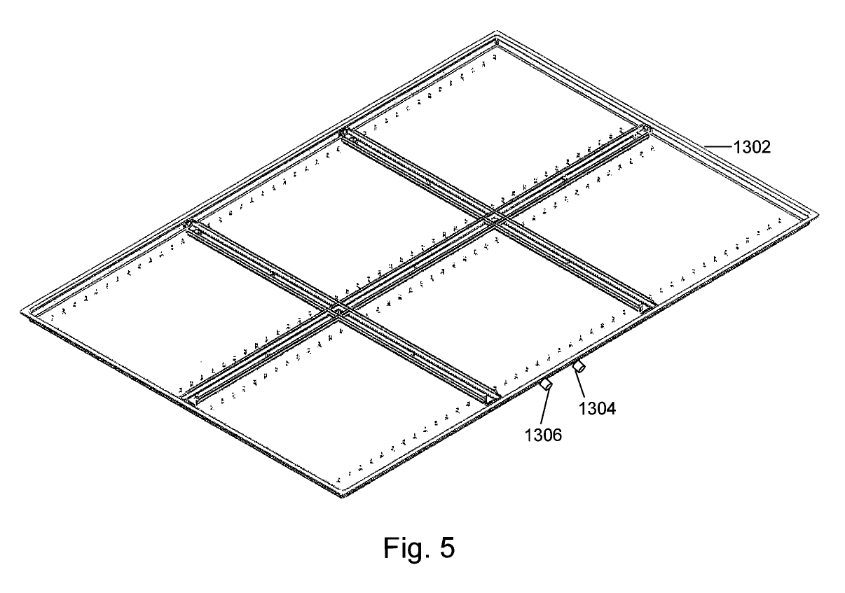

FIG. 5 is a perspective view of a base substrate 1302, in accordance with an embodiment of the present invention. With reference to FIG. 5, base substrate 1302 includes a positive terminal 1304, a negative terminal 1306 to which the external devices can be connected for drawing electricity from the photovoltaic module. A positive terminal 1304 may be several in numbers and may be at any position on the base substrate 1302. Similarly, a negative terminal 1306 may be several in numbers and may be at any position on the base substrate 1302.

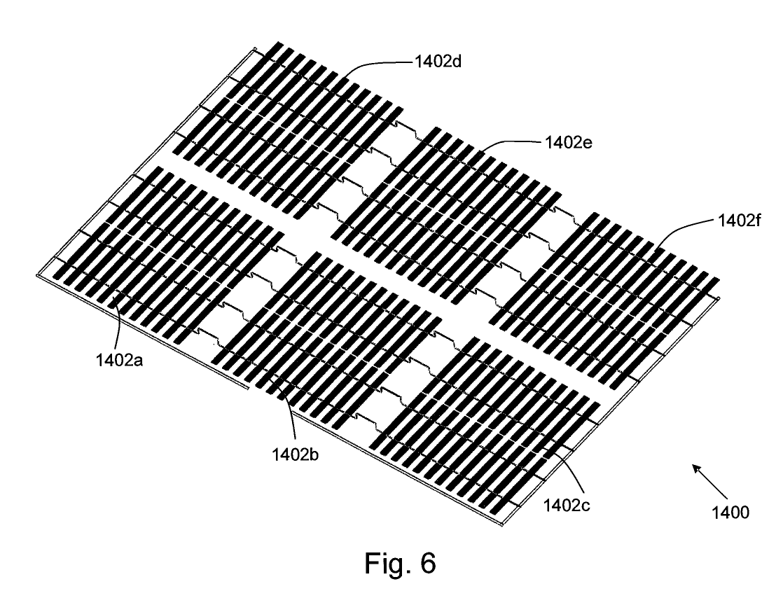

FIG. 6 is a perspective view of a string configuration 1400 of photovoltaic strips, in accordance with an embodiment of the present invention. A string 1402a, a string 1402b, a string 1402c, a string 1402d, a string 1402e and a string 1402f are formed by stringing a plurality of photovoltaic strips in series. String 1402a, string 1402b and string 1402c are combined in series. Similarly, string 1402d, string 1402e and string 1402f are combined in series. These two series configurations are then combined in parallel. String configuration 1400 is arranged over base substrate 1302, in accordance with an embodiment of the present invention.

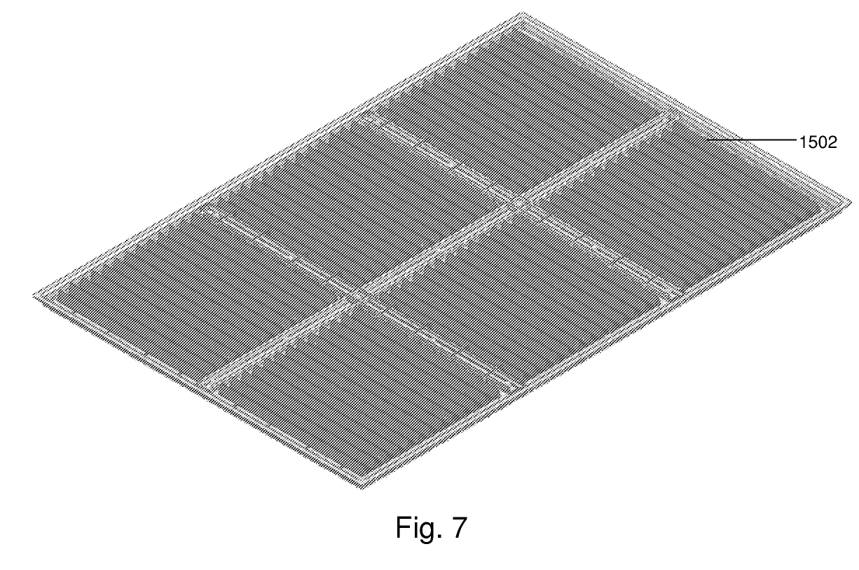

FIG. 7 is a perspective view illustrating optical vees 1502 placed with string configuration 1400, in accordance with an embodiment of the present invention. A plurality of molded EVA elements (not shown in the figure) is formed by pouring molten/semi-molten EVA over string configuration 1400 and optical vees 1502. The molded EVA elements are optically coupled to the photovoltaic strips in string configuration 1400. The molded EVA elements form a trapezoidal shape in cross-section, complementary to optical vees 1502.

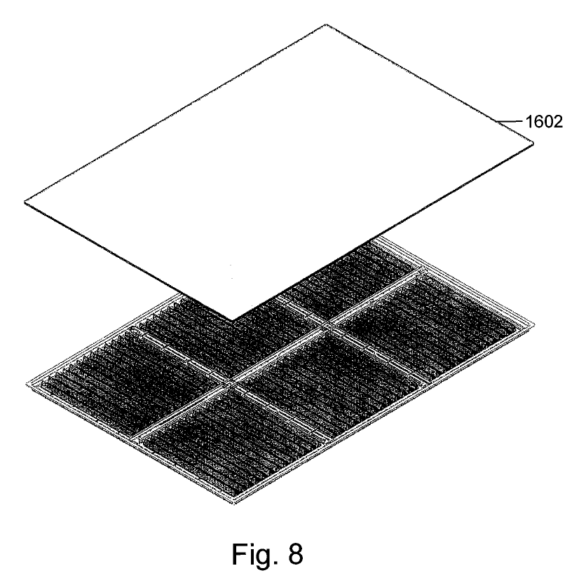

FIG. 8 is a perspective view illustrating a lay-up of a transparent member 1602 over the molded EVA elements, in accordance with an embodiment of the present invention. The shape of the transparent member may, for example, be flat or curved.

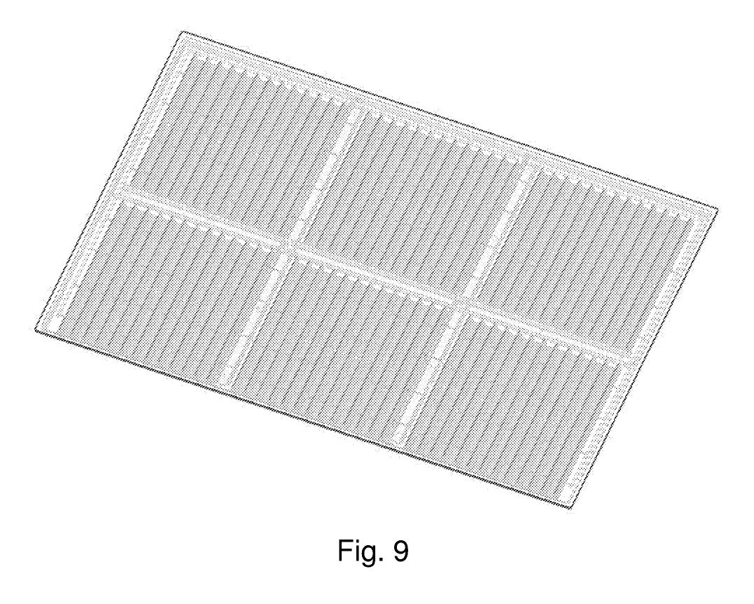

FIG. 9 is a perspective view of the photovoltaic module so formed, in accordance with an embodiment of the present invention. It is to be understood that the specific designation for the photovoltaic module and its components as shown in FIGS. 5-9 is for the convenience of the reader and is not to be construed as limiting the photovoltaic module and its components to a specific number, size, shape, type, material, or arrangement.

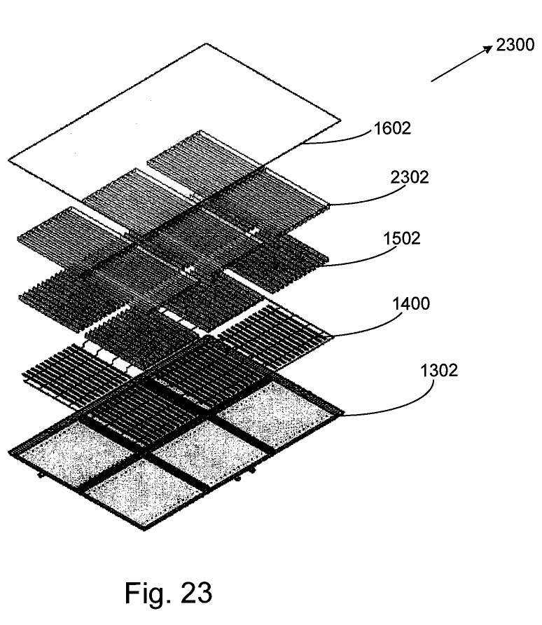

FIG. 23 is a blown-up view of a photovoltaic module 2300, in accordance with an embodiment of the present invention. With reference to FIG. 23, string configuration 1400 is arranged over a base substrate 1302. Optical vees 1502 are aligned and placed in the spaces between photovoltaic strips of string configuration 1400 such that a plurality of trapezoidal cavities is formed between optical vees 1502. Molded concentrating elements 2302 are formed over the trapezoidal cavities by pouring a polymeric material in a fluid state. Molded concentrating elements 308 are molded in the shape of the trapezoidal cavities. Transparent member 1602 is positioned over optical vees 1502.

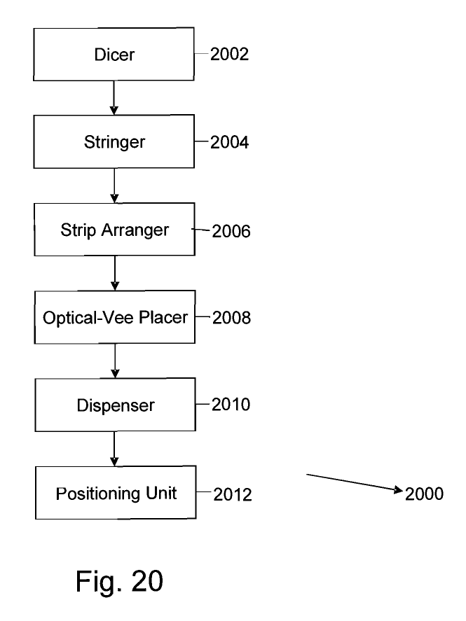

FIG. 20 illustrates a system 2000 for manufacturing photovoltaic module 300, in accordance with an embodiment of the present invention. System 2000 includes a dicer 2002, a stringer 2004, a strip arranger 2006, an optical-vee placer 2008, a dispenser 2010 and a positioning unit 2012.

In an embodiment of the present invention, dicer 2002 dices a semiconductor wafer to form a plurality of photovoltaic strips. Dicer 2002 may, for example, be a mechanical saw or a laser dicer. Laser dicers dice a semiconductor wafer from its p-side using a laser source. This provides a clean cut without any burrs, and involves minimal material damage.

Stringer 2004 connects the photovoltaic strips through one or more conductors in a predefined manner, such that one or more strings of photovoltaic strips are formed. The photovoltaic strips are connected such that spaces are formed in between adjacent photovoltaic strips. Stringer 2004 may, for example, perform soldering using a manual process, a semi-automatic process, or a high-speed soldering machine. Solder-coated copper strips may, for example, be used as the conductors. Alternatively, stringer 2004 may perform wire bonding using a high-speed robotic assembly.

Strip arranger 2006 arranges the strings of photovoltaic strips over a base substrate. Strip arranger 2006 may, for example, be a pick-and-place unit that picks the strings of photovoltaic strips, and aligns and places them as per a specified arrangement.

In accordance with another embodiment of the present invention, strip arranger 2006 arranges individual photovoltaic strips over a base substrate, and stringer 2004 connects the photovoltaic strips with each other over the base substrate. In such a case, strip arranger 2006 may, for example, be a pick-and-place unit that picks photovoltaic strips, and aligns and places them as per a specified arrangement.

Optical-vee placer 2008 places a plurality of optical vees in spaces between the photovoltaic strips. Optical-vee placer 2008 may, for example, be a pick-and-place unit that picks optical vees, and aligns and places them as per the specified arrangement. The optical vees may be fabricated in different ways. Optical vees include a first medium and a second medium underlying the first medium, in accordance with an embodiment of the present invention. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. In accordance with another embodiment of the present invention, the optical vees are solid, and the refractive index of the optical vees is lesser than the refractive index of the molded concentrating elements.

Dispenser 2010 dispenses a polymeric material in a fluid state over said cavities to form one or more molded concentrating elements, such that the molded concentrating elements take the shape of said cavities. In an embodiment of the present invention, the cavities form a trapezoidal shape in cross-section. The polymeric material can be any material that is tolerant to moisture, UV radiation, abrasion, and natural temperature variations. The refractive index of the polymeric material may, for example, be 1.5 or above. Examples of the polymeric material include, but are not limited to, EVA, silicone, TPU, PVB, acrylics, polycarbonates, and synthetic resins. Dispensing unit 2010 mixes the polymeric material with a hardener before pouring the polymeric material, in accordance with an embodiment of the present invention.

In an embodiment of the present invention, positioning unit 2012 positions a transparent member over the optical vees. Positioning unit 2012 may, for example, be a pick-and-place unit that picks the transparent member, and aligns and places it as per the specified arrangement. The transparent member is sealed to the molded concentrating elements, in accordance with an embodiment of the present invention.

Various embodiments of the present invention provide a photovoltaic module for generating electricity from solar energy. The apparatus includes a base substrate, converting means, concentrating means, transparent means and laminating means. The converting means are capable of converting solar energy into electrical energy. The converting means are arranged over the base substrate with spaces in between adjacent converting means. The converting means are connected through conductors in a predefined manner. The concentrating means concentrate solar energy over the converting means. The concentrating means include a plurality of optical vees and one or more molded concentrating elements. The concentrating means is placed over the base substrate as described earlier. The transparent means covers the concentrating means, the converting means and the concentrating means.

The transparent means is coated with an anti-reflective coating to reduce loss of solar energy incident on the photovoltaic module, in accordance with an embodiment of the present invention.

Examples of the base substrate include, but are not limited to, base substrate 302 and base substrate 1302. Examples of the converting means include, but are not limited to, photovoltaic strips 304, and string configuration 1400. Examples of the means for conducting include, but are not limited to, conductors 502a-d. Examples of the concentrating means include, but are not limited to, optical vees 306 and molded concentrating elements 308. Examples of the transparent means include, but are not limited to, transparent member 310 and transparent member 1602.

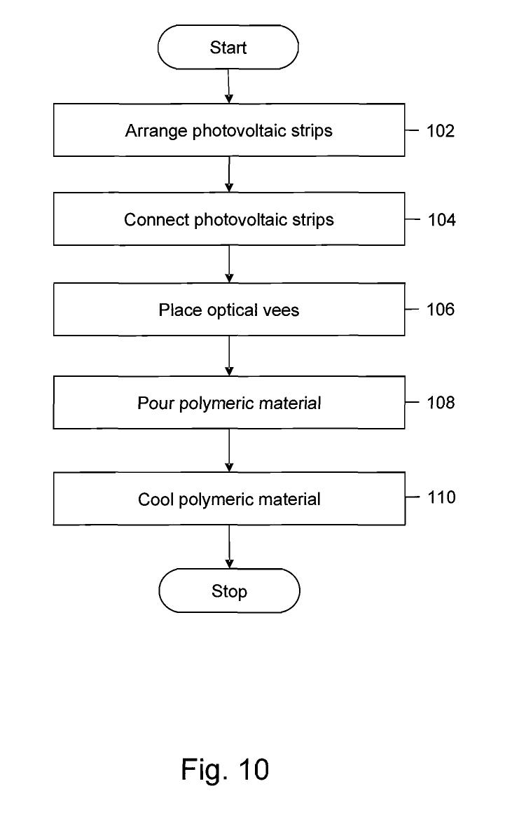

FIG. 10 is a flow diagram illustrating a method for fabricating a photovoltaic module, in accordance with an embodiment of the present invention. At step 102, one or more photovoltaic strips are arranged over a base substrate in a predefined manner. As mentioned earlier, for example, the photovoltaic strips may be rectangular in shape, and may be arranged parallel to each other with spaces in between two adjacent photovoltaic strips. Alternatively, the photovoltaic strips may be circular or arc-like in shape, and may be arranged in the form of concentric circles. The photovoltaic strips may also be square, triangular, or any other shape, in accordance with a desired configuration. At step 104, the photovoltaic strips are connected through one or more conductors. The photovoltaic strips may be connected in series and/or parallel.

At step 106, a plurality of optical vees is placed in the spaces between the photovoltaic strips, such that one or more cavities are formed between adjacent optical vees. For example, the optical vees may be placed in a manner that each photovoltaic strip has two adjacent optical vees. Depending on the shape and configuration of the photovoltaic strips, optical vees with a suitable shape may be used. Continuing from previous examples, rectangular optical vees may be used for rectangular photovoltaic strips, while circular optical vees may be used for circular photovoltaic strips. In accordance with an embodiment of the present invention, the optical vees form an inverted-V shape in cross-section, and therefore, the cavities between these optical vees form a trapezoidal shape in cross-section.

At step 108, a polymeric material in a fluid state, such as a molten or a semi-molten state, is poured over the photovoltaic strips and the optical vees, such that the polymeric material fills the cavities between the optical vees. These cavities enable molding of the polymeric material, with no space or air bubble left between the polymeric material and the photovoltaic strips, and between the polymeric material and the optical vees. This process may be aided by carrying out the molding under vacuum. At step 110, the polymeric material is cured to form one or more molded concentrating elements. These molded concentrating elements concentrate solar energy over the photovoltaic strips. These molded concentrating elements are molded in the shape of the cavities between the optical vees. In accordance with an embodiment of the present invention, the molded concentrating elements form a trapezoidal shape in cross-section. The molded concentrating elements are optically coupled to the photovoltaic strips. As mentioned above, no space or air bubble is left between the molded concentrating elements and the optical vees, and between the molded concentrating elements and the photovoltaic strips.

In accordance with an embodiment of the present invention, each optical vee includes a first medium and a second medium underlying the first medium. The ratio of the refractive index of the first medium and the refractive index of the second medium is greater than one. The refractive index of the first medium is substantially similar to the refractive index of the molded concentrating elements. Examples of the first medium include, but are not limited to, plastics, glass, acrylics, and transparent polymeric materials. Examples of the second medium include, but are not limited to, air and vacuum. A medium boundary is formed at the interface of the first medium and the second medium, at a predefined angle, such that rays within an angular deviation from the normal incident to the base substrate are total internally reflected at the medium boundary and fall on the photovoltaic strips. In accordance with another embodiment of the present invention, the optical vees are solid, and the refractive index of the optical vees is lesser than the refractive index of the molded concentrating elements. In such a case, a medium boundary is formed at the interface of the optical vees and the molded concentrating elements, at a predefined angle, such that rays incident within an angular limit of normal to the base substrate are total internally reflected at the medium boundary and fall on the photovoltaic strips. In this way, electromagnetic radiation falling on the molded concentrating elements is concentrated over the photovoltaic strips. In order to increase the efficiency of concentration, various parameters, the refractive indexes of the optical vees and the molded concentrating elements, and the angle of the optical vees, may be manipulated. For example, the molded concentrating elements may be coated with an anti-reflective coating to reduce loss of solar energy incident on the photovoltaic module. In such a case, no reflection occurs at the surface of the molded concentrating elements, thereby increasing the efficiency of concentration. In accordance with an embodiment of the present invention, no refraction occurs at a medium boundary between the first medium of the optical vees and the molded concentrating elements, when the refractive index of the first medium of the optical vees is substantially similar to the refractive index of the molded concentrating elements. In such a case, the medium boundary between the first medium and the molded concentrating elements is optically transparent. The refractive indexes of the molded concentrating elements and the first medium are more than the refractive index of air or vacuum. Details of how the electromagnetic radiation is concentrated over the photovoltaic strips have been provided in conjunction with FIGS. 13 and 14.

The optical vees may, for example, be made of any material that provides desired optical properties. Examples of such material include, but are not limited to, glass, plastics, and acrylic. The polymeric material can be any material that is tolerant to moisture, UV radiation, abrasion, and natural temperature variations. The refractive index of the polymeric material may, for example, be 1.5 or above. Examples of the polymeric material include, but are not limited to, EVA, silicone, TPU, PVB, acrylics, polycarbonates, and synthetic resins.

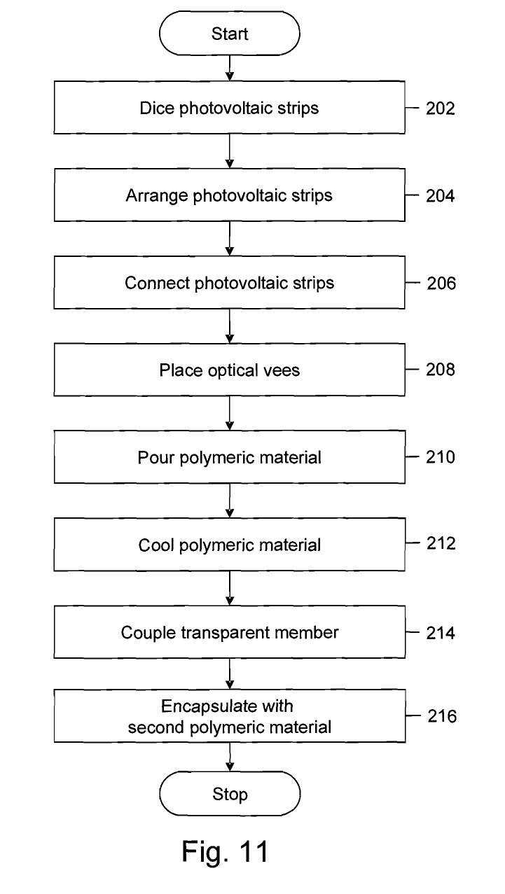

FIG. 11 is a flow diagram illustrating a method for fabricating a photovoltaic module, in accordance with another embodiment of the present invention. At step 202, a semiconductor wafer is diced to form a plurality of photovoltaic strips. This can be accomplished by mechanical sawing or laser dicing. In laser dicing, a semiconductor wafer is diced from base side using a laser source. This provides a clean cut without any burrs, and involves minimal device damage. At step 204, one or more photovoltaic strips are arranged over a base substrate in a predefined manner. The predefined manner may, for example, be a series and/or parallel arrangement, such that electrical output is maximized. At step 206, the photovoltaic strips are connected through one or more conductors. This can be accomplished by manual soldering or soldering by using a high speed robotic assembly. In such a case, solder-coated copper strips may be used as the conductors. As mentioned above, the photovoltaic strips may be connected in series and/or parallel.

At step 208, a plurality of optical vees is placed in the spaces between the photovoltaic strips, such that one or more cavities are formed between adjacent optical vees. As mentioned above, the optical vees may be placed in a manner that each photovoltaic strip has two adjacent optical vees. The optical vees include a first medium and a second medium underlying the first medium, in accordance with an embodiment of the present invention. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. In accordance with another embodiment of the present invention, the optical vees include a single medium. Depending on the shape and configuration of the photovoltaic strips, optical vees with a suitable shape may be used. For example, rectangular optical vees may be used for rectangular photovoltaic strips. In accordance with an embodiment of the present invention, these optical vees form an inverted-V-shape in cross-section, and therefore, the cavities between these optical vees form a trapezoidal shape in cross-section.

At step 210, a polymeric material in a fluid state, such as a molten or a semi-molten state, is poured over the photovoltaic strips and the optical vees, such that the polymeric material fills the cavities between the optical vees. These cavities enable molding of the polymeric material, with no space or air bubble left between the polymeric material and the photovoltaic strips, and between the polymeric material and the optical vees. At step 212, the polymeric material is cured to form one or more molded concentrating elements. These molded concentrating elements concentrate solar energy over the photovoltaic strips. These molded concentrating elements take the shape of the cavities in cross-section. In accordance with an embodiment of the present invention, the molded concentrating elements form a trapezoidal shape in cross-section. The molded concentrating elements are optically coupled to the photovoltaic strips. As mentioned above, no space or air bubble is left between the molded concentrating elements and the optical vees, and between the molded concentrating elements and the photovoltaic strips. Therefore, optical defects are minimized. As mentioned above, the polymeric material can be any material that is tolerant to moisture, UV radiation, abrasion, and natural temperature variations.

At step 214, a transparent member is positioned coupled over the molded concentrating elements. The transparent member is optically coupled to the molded concentrating elements. The transparent member is optically transparent, and protects the molded concentrating elements and the photovoltaic strips from environmental damage, while allowing electromagnetic radiation falling on its surface to pass to the molded concentrating elements. It is desirable that the polymeric material has properties suitable for adhesion to glass. The refractive index of the polymeric material may, for example, be 1.5 or above. Examples of the polymeric material include, but are not limited to, EVA, silicone, TPU, PVB, acrylics, polycarbonates, and synthetic resins. The transparent member may, for example, be a toughened glass with low iron content, or be made of a polymeric material.

In order to increase the efficiency of concentration, various parameters, such as the reflectivity of the transparent member, and the refractive indexes of the transparent member and the molded concentrating elements, may be manipulated. For example, the transparent member may be coated with an anti-reflective coating to reduce loss of solar energy incident on the photovoltaic module. In such a case, reflection occurrings at a medium boundary between air and the transparent member is minimized, thereby increasing the efficiency of concentration. In addition, no refraction occurs at a medium boundary between the transparent member and the molded concentrating elements when the refractive index of the transparent member is substantially similar to the refractive index of at least a portion of the molded concentrating elements. In such a case, the medium boundary between the transparent member and the molded concentrating elements is optically transparent. Rays incident on the medium boundary refract with an angle of refraction smaller than an angle of incidence when the refractive index of the transparent member is less than the refractive index of the molded concentrating elements. Details of these parameters have been provided in conjunction with FIGS. 13 and 14.

At step 216, the photovoltaic strips are encapsulated with a second polymeric material to form a laminate. The process of lamination is performed at a prescribed temperature and/or pressure in a vacuum environment using a laminator. The vacuum environment ensures that no air bubbles are formed within the laminate. In order to avoid heat sinking during lamination, a supporting substrate can be used as a heat barrier, and removed later.

The second polymeric material can be any material that is tolerant to moisture, UV radiation, abrasion, and natural temperature variations. Examples of the second polymeric material include, but are not limited to, EVA, silicone, TPU, acrylic, polycarbonates, and synthetic resins, which can be laminated. In accordance with an embodiment of the present invention, the second polymeric material is the same as the polymeric material used at step 210 and 212.

As the seal at the edge of the photovoltaic module so formed may remain non-hermetic, an additional step of framing the photovoltaic module may be performed. This can be accomplished by mechanically attaching an aluminum frame to the laminate.

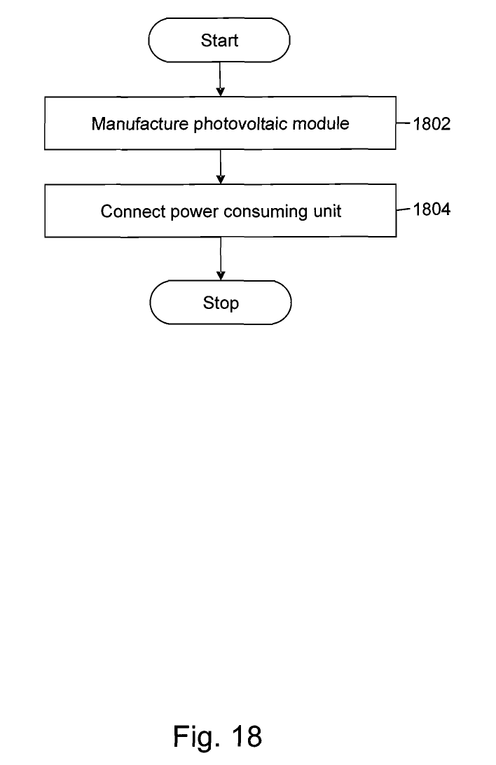

FIG. 18 illustrates a method for manufacturing a system for generating electricity from solar energy, in accordance with an embodiment of the present invention.

At step 1802, a photovoltaic module is manufactured as described in FIGS. 1, 2, 3, 10 and 11. The photovoltaic module may be similar to photovoltaic module 300. At step 1804, a power-consuming unit is connected to the photovoltaic module. The power-consuming unit consumes and/or stores the charge generated by the photovoltaic module. Examples of the power-consuming unit may include a battery or a utility grid. The power-consuming unit may be used to supply power to various devices.

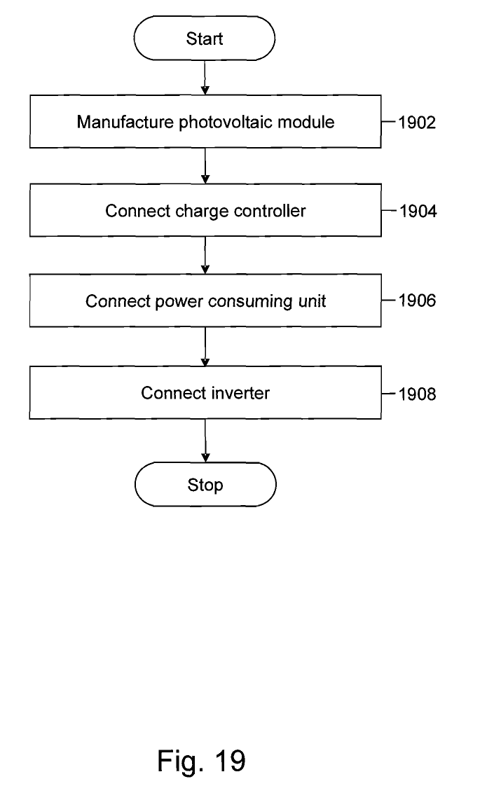

FIG. 19 illustrates a method for manufacturing a system for generating electricity from solar energy, in accordance with another embodiment of the present invention.

At step 1902, a photovoltaic module is manufactured as described in FIGS. 1, 2, 3, 10 and 11. At step 1904, a charge controller is connected with the photovoltaic module. At step 1906, a power-consuming unit is connected to the charge controller. The charge controller controls the amount of charge stored in the power-consuming unit. For example, if the amount of charge stored in the power-consuming unit exceeds a predefined value of the charge stored in the power-consuming unit, the charge controller disconnects the further charging of the power-consuming unit by the photovoltaic module. Further, if the charge stored in the power-consuming unit decreases to a threshold value it starts charging of the power-consuming unit. In an embodiment of the present invention, the predefined value and the threshold value are between the minimum and the maximum capacity of consuming charge in the power-consuming unit.

The power-consuming unit provides the electricity in the first form. The devices that use the first form of electricity may directly be connected to the power-consuming unit. However, if the devices don't use the first form of electricity, as generated by the power-consuming unit, at step 1908, an inverter is connected with the power-consuming unit. The inverter converts the electricity from a first form, as stored in the power-consuming unit, to a second form. Examples of the first form and the second form include the direct current and the alternate current.

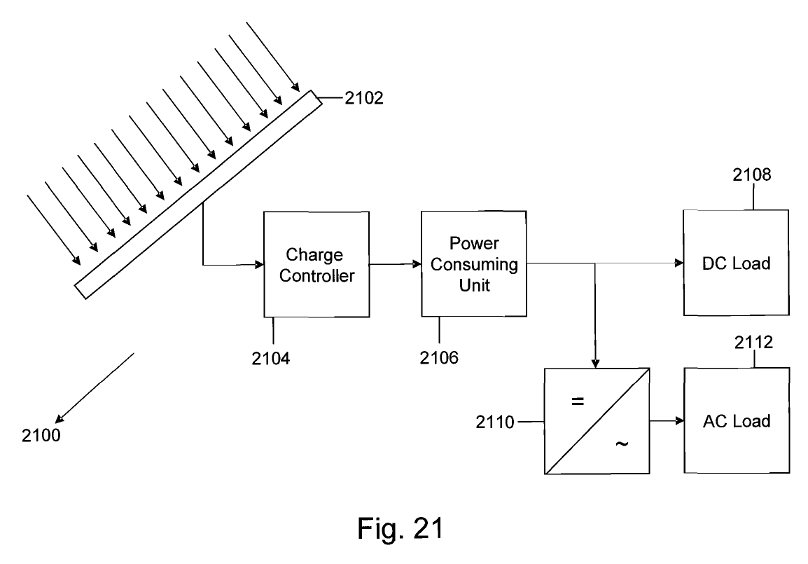

FIG. 21 illustrates a system 2100 for generating electricity from solar energy, in accordance with an embodiment of the present invention. System 2100 includes a photovoltaic module 2102, a charge controller 2104, a power-consuming unit 2106, a Direct Current (DC) load 2108, an inverter 2110 and an Alternating Current (AC) load 2112.

Photovoltaic module 2102 generates electricity from the solar energy that falls on photovoltaic module 2102. Photovoltaic module 2102 is similar to photovoltaic module 300 and photovoltaic module 2300. Power-consuming unit 2106 is connected with photovoltaic module 2102. Power-consuming unit 2106 consumes the charge generated by photovoltaic module 2102.

In an embodiment of the present invention, power-consuming unit 2106 stores the charge generated by photovoltaic module 2102. Power-consuming unit 2106 may, for example, be a battery. In an embodiment of the present invention, charge controller 2104 is connected with photovoltaic module 2102 and power-consuming unit 2106. Charge controller 2104 controls the amount of charge stored in power-consuming unit 2106. For example, if charge stored in power-consuming unit 2106 exceeds a first threshold, charge controller 2104 disconnects further storing of charge generated by photovoltaic module 2102 on to power-consuming unit 2106. Similarly, if charge stored in power-consuming unit 2106 falls below a second threshold, charge controller 2104 reinitiates storing of charge from photovoltaic module 2102 on to power-consuming unit 2106. In an embodiment of the present invention, the first threshold and the second threshold lie between the maximum and the minimum capacity of power-consuming unit 2106.

Power-consuming unit 2106 produces electricity in a first form. In an embodiment of the present invention, the first form is a DC that can be utilized by DC load 2108. DC load 2108 may, for example, be a device that operates on DC. In another embodiment of the present invention, the first form is an AC that can be utilized by AC load 2112. AC load 2112 may, for example, be a device that operates on AC.

Inverter 2110 is connected with power-consuming unit 2106. Inverter 2110 converts electricity from the first form to a second form, as required. The second form may be either DC or AC. Consider, for example, that the first form is DC, and a device requires electricity in the second form, that is, AC. Inverter 2110 converts DC into AC.

System 2100 may be implemented at a roof top of a building, for home or office use. Alternatively, system 2100 may be implemented for use with stand-alone electrical devices, such as automobiles and spacecraft.

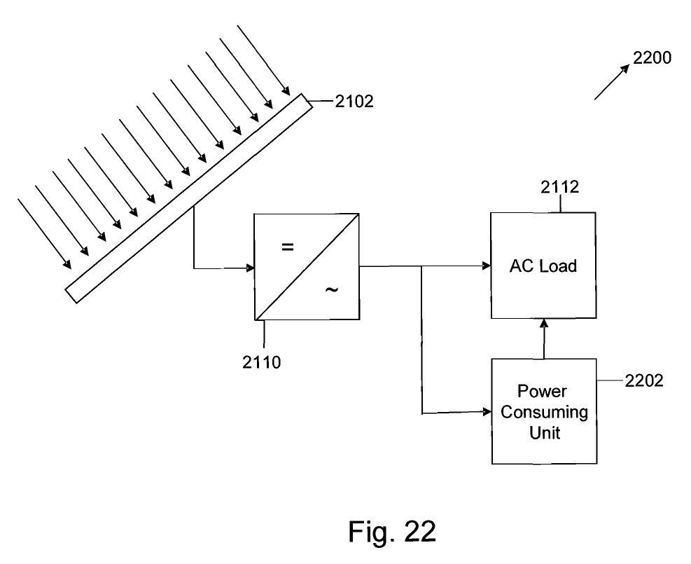

FIG. 22 illustrates a system 2200 for generating electricity from solar energy, in accordance with another embodiment of the present invention. System 2200 includes photovoltaic module 2102, a power-consuming unit 2202, inverter 2110 and AC load 2112.

As mentioned above, inverter 2110 converts electricity generated by photovoltaic module 2102 from the first form to the second form. With reference to FIG. 22, electricity in the second form is utilized by power-consuming unit 2202. Power-consuming unit 2202 may, for example, be a utility grid. For example, an array of photovoltaic modules 2202 may be used to generate electricity on a large scale for grid power supply.

FIG. 13 is a cross-sectional view illustrating how electromagnetic radiation is concentrated over photovoltaic strips 304, in accordance with an embodiment of the present invention. A single low concentrator unit is shown. A single molded concentrating element 308 and a portion of transparent member 310 optically coupled to molded concentrating element 308 are shown. The portion of transparent member 310 has an entry area 802 through which rays enter, while molded concentrating element 308 has an exit area 804 through which the rays exit towards underlying photovoltaic strip.

A medium boundary 806 is formed between molded concentrating element 308 and transparent member 310. With reference to FIG. 13, the refractive index of transparent member 310 is substantially similar to the refractive index of at least a portion of molded concentrating element 308. Therefore, a ray passing from transparent member 310 to molded concentrating element 308 does not refract at medium boundary 806.

A medium boundary 808 is formed between transparent member 310 and air. The refractive index of transparent member 310 is greater than the refractive index of air. Therefore, a ray passing from air to transparent member 310 is refracted towards the normal to medium boundary 808, i.e., the angle of refraction is smaller than the angle of incidence.

A medium boundary 810a and a medium boundary 810b may be formed between the first medium and the second medium of optical vees (not shown in the figure) optically coupled to concentrating element 308 on both sides, where the refractive indexes of concentrating element 308 and the first medium are greater than the refractive index of the second medium. Alternatively, medium boundary 810a and medium boundary 810b may be formed between optical vees (not shown in the figure) and concentrating element 308, where the refractive index of the optical vees is less than the refractive index of concentrating element 308. Medium boundary 810a and medium boundary 810b are hereinafter referred as medium boundaries 810. Rays incident on medium boundaries 810 undergo total internal reflection, when the angle of incidence is greater than the critical angle. The critical angle is defined as the angle of incidence at which a ray is refracted such that it travels along the medium boundary.

With reference to FIG. 13, a ray 812 is incident on entry area 802 at an angle of incidence equal to zero. Ray 812 passes through transparent member 310 and molded concentrating element 308 without any refraction. When incident on medium boundary 810a, ray 812 undergoes total internal reflection, and falls on exit area 804.

With reference to FIG. 13, a ray 814 is incident on entry area 802 at a non-zero angle of incidence. Ray 814 refracts with an angle of refraction smaller than its angle of incidence, and falls on exit area 804.

With reference to FIG. 13, a ray 816 is incident on entry area 802 at an angle of incidence equal to zero. Ray 816 passes through transparent member 310 and molded concentrating element 308 without any refraction, and falls on exit area 804.

With reference to FIG. 13, a ray 818 is incident on entry area 802 at a non-zero angle of incidence. Ray 818 refracts with an angle of refraction smaller than its angle of incidence. When incident on medium boundary 810b, ray 818 undergoes total internal reflection, and falls on exit area 804.

FIG. 14 is a cross-sectional view illustrating how electromagnetic radiation is concentrated over photovoltaic strips 304, in accordance with another embodiment of the present invention. With reference to FIG. 14, the refractive index of transparent member 310 is less than the refractive index of molded concentrating element 308. Therefore, a ray passing from transparent member 310 to molded concentrating elements 308 is refracted towards the normal to medium boundary 806, i.e., the angle of refraction is smaller than the angle of incidence. As mentioned above, the refractive index of molded concentrating element 308 is substantially similar to the refractive index of the optical vees coupled to concentrating 308.

With reference to FIG. 14, a ray 902 is incident on entry area 802 at an angle of incidence equal to zero. Ray 902 passes through transparent member 310 and molded concentrating element 308 without any refraction. When incident on medium boundary 810a, ray 902 undergoes total internal reflection, and falls on exit area 804.

With reference to FIG. 14, a ray 904 is incident on entry area 802 at a non-zero angle of incidence. Ray 904 refracts with a first angle of refraction smaller than its angle of incidence. When incident on medium boundary 806, ray 904 refracts again, with a second angle of refraction smaller than its angle of incidence at medium boundary 806, and falls on exit area 804. It should be noted here that the angle of incidence at medium boundary 806 is equal to the first angle of refraction.

With reference to FIG. 14, a ray 906 is incident on entry area 802 at an angle of incidence equal to zero. Ray 906 passes through transparent member 310 and molded concentrating element 308 without any refraction, and falls on exit area 804.

With reference to FIG. 14, a ray 908 is incident on entry area 802 at a non-zero angle of incidence. For illustration purposes, the angle of incidence of ray 908 on entry area 802 is kept equal to the angle of incidence of ray 818 (with reference to FIG. 13) on entry area 802. Ray 908 refracts with an angle of refraction smaller than its angle of incidence. When incident on medium boundary 806, ray 908 refracts again, with a second angle of refraction smaller than its angle of incidence at medium boundary 806. Further, when incident on medium boundary 810b, ray 908 undergoes total internal reflection, and falls on exit area 804. It should be appreciated that ray 908, refracted twice at medium boundary 808 and medium boundary 806, has a greater angle of incidence at medium boundary 810b as compared to ray 818.

Further, the level of concentration is measured by the ratio of entry area 802 and exit area 804. In one example, entry area 802 is 23 mm wide and exit area 804 is 12 mm wide. Therefore, the level of concentration is 2:1. In this way, a desired level of concentration can be achieved by varying the shape and size of molded concentrating elements 308.

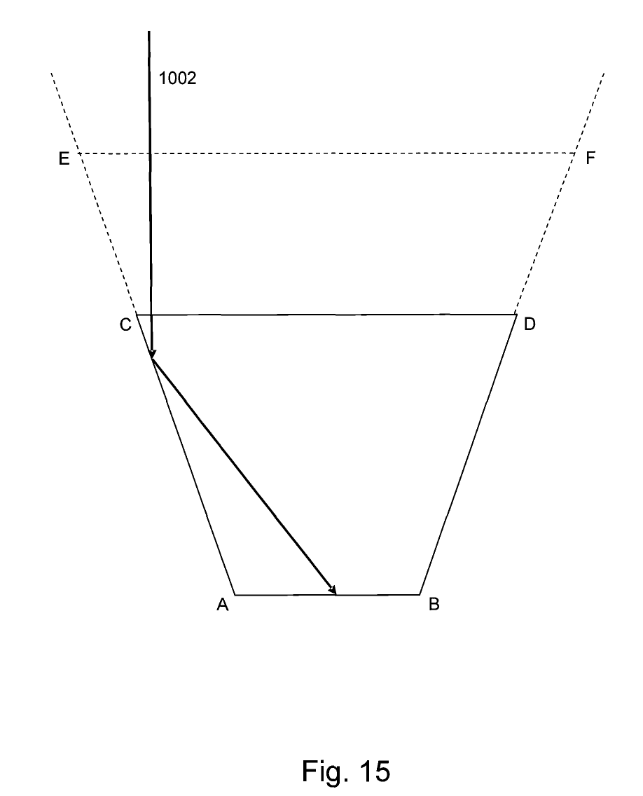

FIG. 15 illustrates how the level of concentration can be varied, in accordance with an embodiment of the present invention. AB represents an exit area through which rays exit, while CD represents a first entry area from where the rays enter. A first level of concentration is equal to the ratio of CD and AB. With reference to FIG. 15, the level of concentration is increased by increasing the height and the width of the molded concentrating element proportionally. EF represents a second entry area. A second level of concentration is equal to the ratio of EF and AB. The second level of concentration is greater than the first level of concentration, as EF is greater than CD.

In case of the first level of concentration, when a ray 1002 falls on side AC, it undergoes total internal reflection towards AB as shown. In case of the second level of concentration, ray 1002 is total internally reflected towards AB in the same manner.

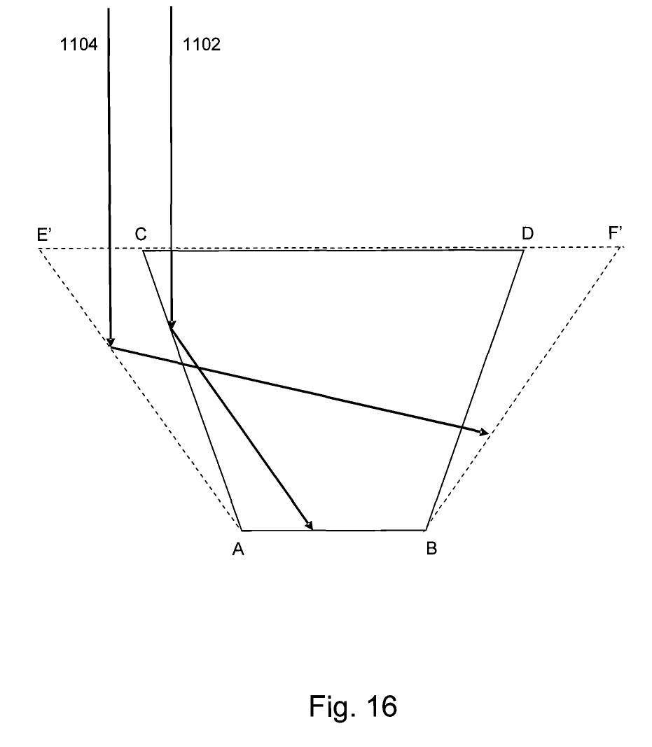

FIG. 16 illustrates how the level of concentration can be varied, in accordance with an embodiment of the present invention. AB represents the exit area, while CD represents the first entry area. The first level of concentration is equal to the ratio of CD and AB. With reference to FIG. 16, the level of concentration is increased by increasing the width of the molded concentrating element without varying its height. E′F′ represents a third entry area. A third level of concentration is numerically equal to the ratio of E′F′ and AB, and the third level of concentration is numerically greater than the first level of concentration, as E′F′ is greater than CD.

In case of the first level of concentration, when a ray 1102 falls on side AC, it undergoes total internal reflection towards AB as shown. In case of the third level of concentration, when a ray 1104 falls on side AE′, it undergoes total internal reflection towards BF′ as shown, and does not fall on AB. This leads to wastage of solar energy. Therefore, it can be concluded that the actual value of the third level of concentration is less than its numerical value.

It can be concluded that the acceptance angle of photovoltaic module 300 should be chosen appropriately. The acceptance angle is defined as the angle from the normal at which the power output from photovoltaic module 300 drops to a predefined value. The degree of acceptance angle varies with the geometry of the concentrator, which in turn. is dependent on the level of optical concentration. For example, the acceptance angle may vary when the concentration is varied between 5:1 and 1.5:1.

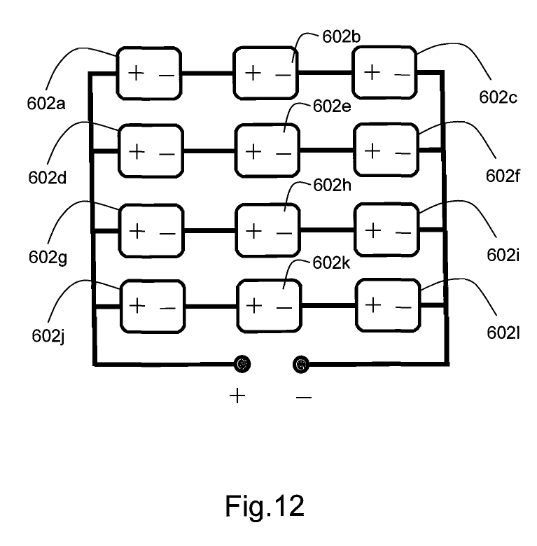

FIG. 12 is a schematic diagram illustrating a configuration of a plurality of photovoltaic strips, in accordance with another embodiment of the present invention. With reference to FIG. 12, the photovoltaic strips are connected in series and parallel, such that the electrical output is maximized. In this configuration, three photovoltaic strips, such as a photovoltaic strip 602a, a photovoltaic strip 602b and a photovoltaic strip 602c, are connected in series to form a first string. Similarly, a photovoltaic strip 602d, a photovoltaic strip 602e and a photovoltaic strip 602f are connected in series to form a second string; a photovoltaic strip 602g, a photovoltaic strip 602h and a photovoltaic strip 602i are connected in series to form a third string; a photovoltaic strip 602j, a photovoltaic strip 602k and a photovoltaic strip 602l are connected in series to form a fourth string. These four strings are then combined in parallel.

It is to be understood that the specific designation for the configuration of photovoltaic strips in FIG. 12 is for the convenience of the reader and is not to be construed as limiting a photovoltaic module to a specific number or arrangement of its components.

The potential difference is directly proportional to the number of photovoltaic strips connected in series, while the current is directly proportional to the number of photovoltaic strips connected in parallel. The photovoltaic strips may be connected in series and parallel to create a configuration with a desired potential difference and current.

Table 1 is an exemplary table illustrating simulation data comparison between various types of photovoltaic modules, in accordance with an embodiment of the present invention.

TABLE 1

| Configuration | Unit | Concentration | Size (in mm) | Iₘ (in A) | Vₘ (in V) | Pₘ (in W) |
|---|---|---|---|---|---|---|
| 1 × 1 | Strip | 1:1 | 156 × 156 | 7.110 | 0.477 | 3.39 |
| 1 × 1 | Strip | 1:1 | 156 × 12 | 0.547 | 0.477 | 0.26 |
| 12 × 1 | Strip | 1:1 | 156 × 12 | 0.547 | 5.723 | 3.13 |
| 3 (series) × 4 | String | 1:1 | 156 × 12 × 12 | 2.188 | 17.172 | 37.57 |
| (parallel) | | | | | | |
| 3 (series) × 4 | String | 2:1 | 156 × 12 × 12 | 4.376 | 17.172 | 75.14 |
| (parallel) | | | | | | |
| 3 (series) × 4 | String | 3:1 | 156 × 12 × 12 | 6.564 | 17.172 | 112.72 |
| (parallel) | | | | | | |
| 3 (series) × 4 | String | 4:1 | 156 × 12 × 12 | 8.752 | 17.172 | 150.29 |
| (parallel) | | | | | | |
| 3 (series) × 4 | String | 5:1 | 156 × 12 × 12 | 10.94 | 17.172 | 187.86 |
| (parallel) | | | | | | |

With reference to Table 1,
‘Configuration’ denotes the configuration in which one or more photovoltaic strips are arranged to form a photovoltaic module;
‘Unit’ denotes the unit of the said configuration
‘Concentration’ denotes the level of concentration used in the photovoltaic module;
‘Size’ denotes the size of the photovoltaic strips used, in mm;
‘Im’ denotes the maximum current attained in the photovoltaic module, in ampere (A);
‘Vm’ denotes the maximum potential difference attained in the photovoltaic module, in volt (V); and
‘Pₘ’ denotes the maximum power developed in the photovoltaic module, in watt (W).

A first photovoltaic module has the configuration of ‘1×1’, the concentration of ‘1:1’ and the size of ‘156 mm×156 mm’. This implies that a single semiconductor wafer of size 156 mm×156 mm has been used without an additional concentrator.

The single semiconductor wafer is diced into 13 photovoltaic strips of size ‘156 mm×12 mm’ each. A second photovoltaic module is formed by a single photovoltaic strip of size 156 mm×12 mm without an additional concentrator.

A third photovoltaic module is formed by connecting 12 photovoltaic strips of size ‘156 mm×12 mm’ in series, without an additional concentrator. The 12 photovoltaic strips form one photovoltaic string.

A fourth photovoltaic module is formed by connecting three photovoltaic strings of size ‘156 mm×12 mm×12 nos.’ in series and combining four such configurations in parallel, without an additional concentrator. With reference to Table 1, the maximum current attained in the fourth photovoltaic module is four times the maximum current attained in the third photovoltaic module, while the maximum potential difference attained in the fourth photovoltaic module is thrice the maximum potential difference attained in the third photovoltaic module. Consequently, the maximum power developed in the fourth photovoltaic module is 12 times the maximum power developed in the third photovoltaic module.

A fifth photovoltaic module is formed by connecting three photovoltaic strings of size ‘156 mm×12 mm×12 nos.’ in series and combining four such configurations in parallel, with a concentrator providing a level of concentration of two. With reference to Table 1, the maximum current attained in the fifth photovoltaic module is twice the maximum current attained in the fourth photovoltaic module. Consequently, the maximum power developed in the fifth photovoltaic module is twice the maximum power developed in the fourth photovoltaic module.

A sixth photovoltaic module is formed by connecting three photovoltaic strings of size ‘156 mm×12 mm×12 nos.’ in series and combining four such configurations in parallel, with a concentrator providing a level of concentration of three. With reference to Table 1, the maximum current attained in the sixth photovoltaic module is thrice the maximum current attained in the fourth photovoltaic module. Consequently, the maximum power developed in the sixth photovoltaic module is thrice the maximum power developed in the fourth photovoltaic module.

A seventh photovoltaic module is formed by connecting three photovoltaic strings of size ‘156 mm×12 mm×12 nos.’ in series and combining four such configurations in parallel, with a concentrator providing a level of concentration of four. With reference to Table 1, the maximum current attained in the seventh photovoltaic module is four times the maximum current attained in the fourth photovoltaic module. Consequently, the maximum power developed in the seventh photovoltaic module is four times the maximum power developed in the fourth photovoltaic module.

An eighth photovoltaic module is formed by connecting three photovoltaic strings of size ‘156 mm×12 mm×12 nos.’ in series and combining four such configurations in parallel, with a concentrator providing a level of concentration of five. With reference to Table 1, the maximum current attained in the eighth photovoltaic module is five times the maximum current attained in the fourth photovoltaic module. Consequently, the maximum power developed in the eighth photovoltaic module is five times the maximum power developed in the fourth photovoltaic module. It should be appreciated that the maximum current attained and the maximum power developed in a photovoltaic module are directly proportional to the level of concentration provided in the photovoltaic module.

Table 2 is an exemplary table illustrating simulation data comparison between various types of photovoltaic modules, in accordance with another embodiment of the present invention.

TABLE 2

| Configuration | Unit | Concentration | Size (in mm) | Iₘ (in A) | Vₘ (in V) | Pₘ (in W) |
|---|---|---|---|---|---|---|
| 1 × 1 | Strip | 1:1 | 125 × 125 | 4.90 | 0.48 | 2.35 |
| 1 × 1 | Strip | 1:1 | 125 × 12 | 0.47 | 0.48 | 0.23 |
| 12 × 1 | Strip | 1:1 | 125 × 12 | 0.47 | 5.76 | 2.71 |
| 3 (series) × 4 | String | 1:1 | 125 × 12 × 12 | 1.88 | 17.28 | 31.51 |
| (parallel) | | | | | | |
| 3 (series) × 4 | String | 2:1 | 125 × 12 × 12 | 3.76 | 17.28 | 65.03 |
| (parallel) | | | | | | |
| 3 (series) × 4 | String | 3:1 | 125 × 12 × 12 | 5.64 | 17.28 | 97.46 |
| (parallel) | | | | | | |
| 3 (series) × 4 | String | 4:1 | 125 × 12 × 12 | 7.52 | 17.28 | 129.95 |
| (parallel) | | | | | | |
| 3 (series) × 4 | String | 5:1 | 125 × 12 × 12 | 9.40 | 17.28 | 162.43 |
| (parallel) | | | | | | |

With reference to Table 2,
‘Configuration’, ‘Unit’, ‘Concentration’, ‘Size’, ‘Im’, ‘Vm’, and ‘Pₘ’ definitions are in reference with Table 1.

Similarly, in reference to Table 2, a first photovoltaic module has the configuration of ‘1×1’, the concentration of ‘1:1’ and the size of ‘125 mm×125 mm’. This implies that a single semiconductor wafer of size 125 mm×125 mm has been used without an additional concentrator. The single semiconductor wafer is diced into 13 photovoltaic strips of size ‘125 mm×12 mm’ each. A second photovoltaic module is formed by a single photovoltaic strip of size 125 mm×12 mm without an additional concentrator. A third photovoltaic module is formed by connecting 12 photovoltaic strips of size ‘125 mm×12 mm’ in series, without an additional concentrator. The 12 photovoltaic strips form one photovoltaic string. A fourth photovoltaic module is formed by connecting three photovoltaic strings of size ‘125 mm×12 mm×12 nos.’ in series and combining four such configurations in parallel, without an additional concentrator. As described earlier in Table 1, Table 2 also shows the maximum power developed in the fourth photovoltaic module is 12 times the maximum power developed in the third photovoltaic module. A fifth photovoltaic module, a sixth photovoltaic module, a seventh photovoltaic module and a eighth photovoltaic module are formed by connecting three photovoltaic strings of size ‘125 mm×12 mm×12 nos.’ in series and combining four such configurations in parallel, with concentrators providing a level of concentration of two, three, four and five respectively. With reference to Table 2, the maximum current attained in the fifth photovoltaic module, sixth photovoltaic module, seventh photovoltaic module and eighth photovoltaic module is respectively twice, thrice, four times and five times the maximum current attained in the fourth photovoltaic module. Consequently, the maximum power developed in the fifth photovoltaic module, sixth photovoltaic module, seventh photovoltaic module and eighth photovoltaic module is respectively twice, thrice, four times and five times the maximum power developed in the fourth photovoltaic module.

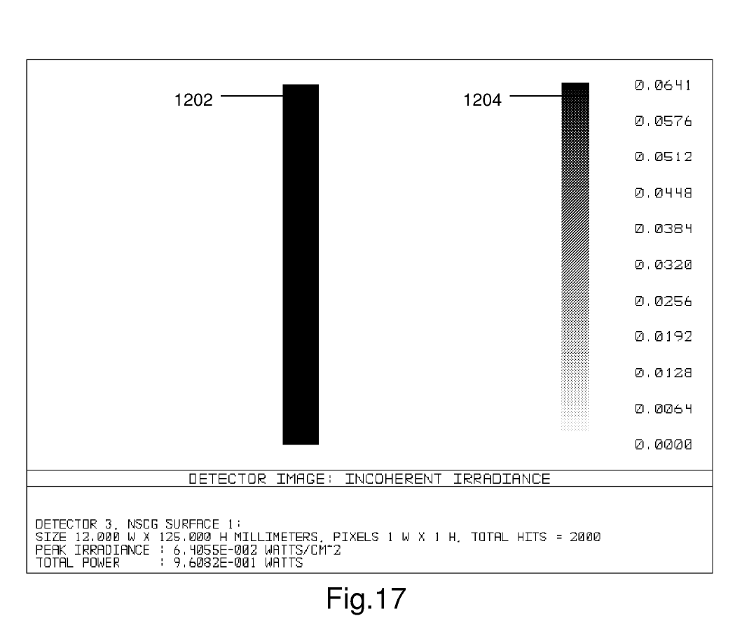

FIG. 17 illustrates a simulation of the output of a photovoltaic strip of size 125 mm×12 mm, in accordance with an embodiment of the present invention. An opaque rectangle 1202 denotes a detector, while a shaded rectangle 1204 denotes that the output is uniform from each part of the photovoltaic strip. The input irradiance over a molded concentrating element, optically coupled with the photovoltaic strip, is 1 watt, while the power at the detector side is 0.96 watt. Therefore, the optical efficiency of the photovoltaic strip is 96%.

Embodiments of the present invention provide a photovoltaic module that is suitable for mass manufacturing, has lower cost, and is easy to manufacture compared to conventional low concentrator photovoltaic modules. The photovoltaic module has the same form factor as conventional photovoltaic modules, and therefore, has no special mounting requirements. In addition, the fabrication of the photovoltaic module involves the same processes as well as machines as required for fabricating existing flat photovoltaic modules with optical vees and molded concentrating elements.

Further, molded concentrating elements are not formed separately, and are rather formed by pouring a suitable polymeric material over photovoltaic strips and optical vees. This minimizes optical defects, such as void spaces and air bubbles within the photovoltaic module, while quickening the process of fabrication.

Furthermore, the photovoltaic module provides maximized outputs, at appropriate configurations of the photovoltaic strips and appropriate levels of concentration. Moreover, the photovoltaic module is made of photovoltaic strips, which are arranged with spaces in between two adjacent photovoltaic strips. Therefore, the photovoltaic module requires lesser amount of semiconductor material to produce the same output, as compared to conventional low concentrator photovoltaic modules.

This application may disclose several numerical range limitations that support any range within the disclosed numerical ranges even though a precise range limitation is not stated verbatim in the specification because the embodiments of the invention could be practiced throughout the disclosed numerical ranges. Finally, the entire disclosure of the patents and publications referred in this application, if any, are hereby incorporated herein in entirety by reference.

1. A photovoltaic module for generating electricity from solar energy, said photovoltaic module comprising:
a base substrate;
one or more photovoltaic strips arranged over said base substrate, wherein spaces are formed in between adjacent photovoltaic strips;
a plurality of optical vees located in the spaces between said photovoltaic strips, such that one or more cavities are formed between said optical vees; and
one or more molded concentrating elements for concentrating solar energy over said photovoltaic strips, said molded concentrating elements being formed by pouring a polymeric material in a fluid state over said cavities, such that said molded concentrating elements take the shape of said cavities.

2. The photovoltaic module of claim 1 further comprising a transparent member positioned over said molded concentrating elements.

3. The photovoltaic module of claim 2, wherein the refractive index of said transparent member is substantially similar to the refractive index of at least a portion of said molded concentrating elements.

4. The photovoltaic module of claim 2, wherein said transparent member is coated with an anti-reflective coating to reduce loss of solar energy incident on said photovoltaic module.

5. The photovoltaic module of claim 1 further comprising a laminate encapsulating said base substrate, said photovoltaic strips, said optical vees and said molded concentrating elements.

6. The photovoltaic module of claim 1, wherein said photovoltaic strips are connected through one or more conductors in a predefined manner in a series and/or parallel arrangement.

7. The photovoltaic module of claim 1, wherein said optical vees comprise:
a first medium; and
a second medium underlying said first medium, wherein the ratio of the refractive index of said first medium and the refractive index of said second medium is greater than one.

8. The photovoltaic module of claim 7, wherein the refractive index of said first medium is substantially similar to the refractive index of said molded concentrating elements, such that the medium boundary between said first medium and said molded concentrating elements is optically transparent.

9. The photovoltaic module of claim 7, wherein said first medium is selected from the group consisting of a plastic, glass, an acrylic, and a transparent polymeric material.

10. The photovoltaic module of claim 7, wherein said second medium is selected from the group consisting of air and vacuum.

11. The photovoltaic module of claim 1, wherein the refractive index of said molded concentrating elements is greater than the refractive index of said optical vees.

12. The photovoltaic module of claim 1, wherein said polymeric material is selected from the group consisting of ethyl vinyl acetate (EVA), poly vinyl butyral (PVB), a silicone, thermoplastic poly-urethane (TPU), an acrylic, a polycarbonate, and a synthetic resin.

13. A photovoltaic module, said photovoltaic module comprising:
a base substrate;
converting means for converting solar energy into electrical energy, said converting means being arranged being arranged over said base substrate with spaces in between adjacent converting means; and
concentrating means for concentrating solar energy over said converting means, said concentrating means comprising:
a plurality of optical vees placed in the spaces between said photovoltaic strips, such that one or more cavities are formed between said optical vees; and
one or more molded concentrating elements for concentrating solar energy over said photovoltaic strips, said molded concentrating elements being formed by pouring a polymeric material in a fluid state over said cavities, such that said molded concentrating elements take the shape of said cavities.

14. The photovoltaic module of claim 13 further comprising transparent means for covering said concentrating means.

15. The photovoltaic module of claim 13 further comprising a laminating means for encapsulating said base substrate, said converting means, said concentrating means, thereby holding said photovoltaic module together.

16. A system for manufacturing a photovoltaic module, said system comprising:
a strip-arranger for arranging photovoltaic strips over a base substrate, wherein spaces are formed in between adjacent photovoltaic strips, said photovoltaic strips are capable of converting solar energy into electrical energy;
a stringer for connecting said photovoltaic strips through one or more conductors in a predefined manner;
an optical-vee-placer for placing a plurality of optical vees in said spaces between said photovoltaic strips, such that one or more cavities are formed between said optical vees; and
a dispenser for dispensing a polymeric material in a fluid state over said cavities to form one or more molded concentrating elements, such that said molded concentrating elements take the shape of said cavities.

17. The system of claim 16, wherein the refractive index of said molded concentrating elements is greater than the refractive index of said optical vees.

18. The system of claim 16 further comprising a dicer for dicing one or more semiconductor sheets into said photovoltaic strips.

19. The system of claim 16, wherein the predefined manner is a series and/or parallel arrangement, such that electrical output is maximized.

20-33. (canceled)
